(19) United States
(12) Patent Application Publication
(10) Pub. No.: US 2012/0205045 A1
(43) Pub. Date: Aug. 16, 2012

(54) SEMICONDUCTOR MACHINE AND CLEANING PROCESS THEREOF

(75) Inventors: Li-Hsun HO, Hsinchu County (TW); Ching-Shing Huang, Taipei City (TW); Chih-Hui Shen, Taipei County (TW); Tao-Min Chang, Hsinchu County (TW)

(73) Assignee: UNITED MICROELECTRONICS CORP., Hsinchu (TW)

(21) Appl. No.: 13/025,689

(22) Filed: Feb. 11, 2011

(51) Int. Cl. H01L 21/465; B08B 5/00

(52) U.S. Cl. 156/345.1; 134/31; 257/E21.485

(57) ABSTRACT

A semiconductor machine and a cleaning process are provided. The semiconductor machine includes a chamber and a cleaning module. The cleaning process includes the following steps. Firstly, the semiconductor machine is used to perform a semiconductor manufacturing process, wherein a titanium-based material is etched in the semiconductor manufacturing process. Then, a cleaning task is activated to clean the semiconductor machine by using a cleaning agent including a gas mixture of a fluoride compound and oxygen.

### FIELD OF THE INVENTION

The present invention relates to a semiconductor machine, and more particularly to a semiconductor machine with an etch chamber. The present invention also relates to a process of cleaning the semiconductor machine.

### BACKGROUND OF THE INVENTION

In a semiconductor manufacturing process, photomasks are widely used for transferring images to semiconductor chips. After a photoresist is deposited on a surface of a semiconductor chip, the photoresist is exposed with light through a photomask, and then the exposed photoresist is developed. After the exposed and developed photoresist is stripped, the remaining photoresist is served as an etch mask to protect underlying material of the semiconductor chip during a subsequent etching process, thereby defining a pattern layer. However, since some kinds of photoresist materials fail to withstand the subsequent etching process, the use of the remaining photoresist as the etch mask is undesired. For solving these drawbacks, the images formed on the remaining photoresist may be transferred to a hard mask layer, thereby forming a hard mask. In this situation, the hard mask is served as an etch mask to protect underlying material of the semiconductor chip during a subsequent etching process, thereby defining a pattern layer.

The common hard mask is usually made of insulating material such as silicon oxide or silicon nitride. Nowadays, as the semiconductor manufacturing techniques become more diversified, metal hard masks are often used in semiconductor manufacturing processes. However, the use of a titanium-based material as a metal hard mask incurs some drawbacks. For example, during the process of etching or removing the metal hard mask, titanium-based contaminant is easily formed on the wall of the etch chamber. The titanium-based contaminant may adversely affect the subsequent processes. For enhancing the performance, scheduled preventive maintenance (PM) of the semiconductor machine should be performed. Under this circumstance, the product throughput is impaired.

Therefore, there is a need of providing a semiconductor machine and a cleaning process thereof to obviate the drawbacks encountered from the prior art.

### SUMMARY OF THE INVENTION

Therefore, the object of the present invention is to provide a semiconductor machine and a cleaning process thereof so as to enhance the product throughput.

In accordance with an aspect, the present invention provides a process of cleaning a semiconductor machine. Firstly, the semiconductor machine is used to perform a semiconductor manufacturing process, wherein a titanium-based material is etched in the semiconductor manufacturing process. Then, a cleaning task is activated and a cleaning agent including a gas mixture of a fluoride compound and oxygen is used to clean the semiconductor machine.

In an embodiment, the semiconductor manufacturing process is performed in a chamber of the semiconductor machine, and the semiconductor manufacturing process is an etching process of a titanium hard mask.

In an embodiment, the cleaning task is an automatic cleaning task. When a contaminant level of the semiconductor machine exceeds a threshold value, the automatic cleaning task is activated.

In an embodiment, the contaminant level of the semiconductor machine is expressed by a cumulative workload of the semiconductor machine.

In an embodiment, the cumulative workload of the semiconductor machine is a cumulative value of working hours of the semiconductor machine or a cumulative number of processed wafers.

In an embodiment, the cleaning task is performed by a waferless auto clean technology.

In an embodiment, the fluoride compound is carbon tetrafluoride or hexafluoroethane.

In accordance with another aspect, the present invention provides a semiconductor machine. The semiconductor machine includes a chamber and a cleaning module. The chamber is configured for accommodating a semiconductor wafer and performing a semiconductor manufacturing process on the semiconductor wafer, wherein a titanium-based material is etched in the semiconductor manufacturing process. The cleaning module is configured for providing a cleaning agent to clean the chamber, wherein the cleaning agent includes a gas mixture of a fluoride compound and oxygen.

In an embodiment, the semiconductor manufacturing process performed in the chamber is an etching process of a titanium hard mask.

In an embodiment, when a contaminant level of the semiconductor machine exceeds a threshold value, an automatic cleaning task of the cleaning module is activated to provide a cleaning agent to clean the chamber.

In an embodiment, the contaminant level of the semiconductor machine is expressed by a cumulative workload of the semiconductor machine.

In an embodiment, the cumulative workload of the semiconductor machine is a cumulative value of working hours of the semiconductor machine or a cumulative number of processed wafers.

In an embodiment, the fluoride compound is carbon tetrafluoride or hexafluoroethane.

In an embodiment, the chamber further comprises top power and bottom power. During the cleaning module provides the cleaning agent to clean the chamber, the top power is turned on, but the bottom power is turned off.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic diagram illustrating the architecture of a semiconductor machine according to an embodiment of the present invention; and

FIG. 2 is a flowchart illustrating a process of cleaning a semiconductor machine according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

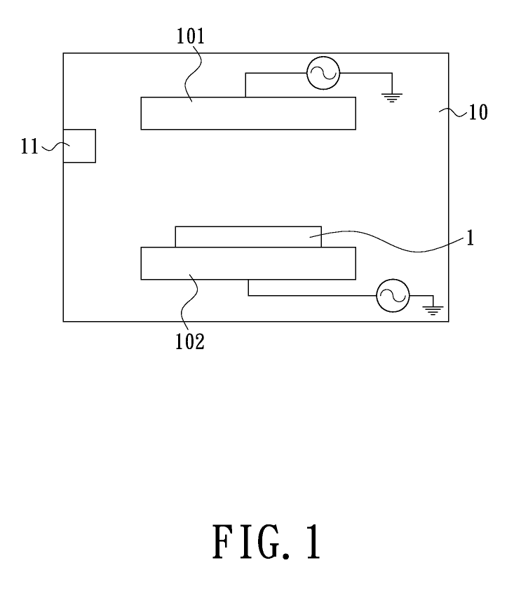

FIG. 1 is a schematic diagram illustrating the architecture of a semiconductor machine according to an embodiment of the present invention. The semiconductor machine has a chamber 10. When a semiconductor wafer 1 is placed in the chamber 10, a semiconductor manufacturing process is performed. For example, the semiconductor manufacturing process includes a process of etching a titanium-based material (e.g. a titanium hard mask). As known, during the process of etching or removing the titanium hard mask, titanium-based contaminant is easily formed on the wall of the etch chamber. The titanium-based contaminant may adversely affect the performance of the subsequent processes. For minimizing the adverse influence of the titanium-based contaminant, a cleaning agent is provided to clean the chamber 10. In an embodiment, the cleaning agent includes a gas mixture of a fluoride compound and oxygen. The fluoride compound includes carbon tetrafluoride (CF4), hexafluoroethane (C2F6), or a mixture thereof. This cleaning agent has good isotropic etching capability to the titanium-based material. After the process of etching the titanium hard mask is performed, an automatic cleaning task is activated to provide the cleaning agent to clean the chamber 10. In accordance with the present invention, a cleaning module 11 is disposed within the chamber 10 for providing the cleaning agent to clean the chamber 10. In a case that the chamber 10 has top power 101 and bottom power 102, the top power 101 is turned on but the bottom power 102 is turned off. In such way, the chamber 10 can be effectively cleaned and the frequency of performing preventive maintenance (PM) of the semiconductor machine will be reduced.

However, it is not necessary to activate an automatic cleaning task of the cleaning module 11 whenever one etching process is performed. Alternatively, in some embodiments, when a contaminant level of the semiconductor machine exceeds a threshold value, the automatic cleaning task of the cleaning module 11 is activated. The contaminant level of the semiconductor machine may be expressed by a cumulative workload of the semiconductor machine. The cumulative workload is for example a cumulative value of working hours of the semiconductor machine or a cumulative number of processed wafers. As a consequence, the product throughput and the cleaning efficacy can be both enhanced.

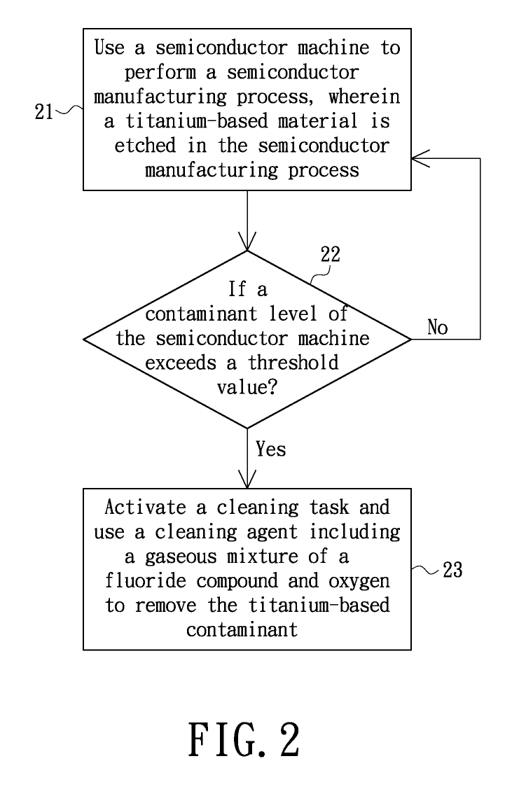

FIG. 2 is a flowchart illustrating a process of cleaning a semiconductor machine according to an embodiment of the present invention. First of all, a semiconductor machine is used to perform a semiconductor manufacturing process, wherein a titanium-based material is etched in the semiconductor manufacturing process (Step 21). Then, Step 22 is performed to judge whether a contaminant level of the semiconductor machine exceeds a threshold value. The contaminant level of the semiconductor machine may be expressed by a cumulative workload of the semiconductor machine. The cumulative workload is for example a cumulative value of working hours of the semiconductor machine or a cumulative number of processed wafers. If the contaminant level is lower than the threshold value, the semiconductor manufacturing process is repeatedly performed (Step 21). Whereas, if the contaminant level exceeds the threshold value, a cleaning task is activated and a cleaning agent including a gas mixture of a fluoride compound and oxygen is used to remove the titanium-based contaminant (Step 23). It is preferred that the cleaning task is performed by a waferless auto clean technology.

In an embodiment, the cleaning agent includes a gas mixture of a fluoride compound and oxygen. The fluoride compound includes carbon tetrafluoride (CF4), hexafluoroethane (C2F6), or a mixture thereof. This cleaning agent has good isotropic etching capability to the titanium-based material. After the process of etching the titanium hard mask is performed, an automatic cleaning task is activated to provide the cleaning agent to clean the chamber of the semiconductor machine. In such way, the chamber 10 can be effectively cleaned and the frequency of performing preventive maintenance (PM) of the semiconductor machine will be reduced.

From the above description, it is found that the product throughput and the cleaning efficacy can be both enhanced by the semiconductor machine and the cleaning process of the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A process of cleaning a semiconductor machine, the process comprising steps of:
using the semiconductor machine to perform a semiconductor manufacturing process, wherein a titanium-based material is etched in the semiconductor manufacturing process; and
activating a cleaning task and using a cleaning agent including a gas mixture of a fluoride compound and oxygen to clean the semiconductor machine.

2. The process of cleaning a semiconductor machine according to claim 1, wherein the semiconductor manufacturing process is performed in a chamber of the semiconductor machine, and the semiconductor manufacturing process is an etching process of a titanium hard mask.

3. The process of cleaning a semiconductor machine according to claim 1, wherein the cleaning task is an automatic cleaning task, wherein when a contaminant level of the semiconductor machine exceeds a threshold value, the automatic cleaning task is activated.

4. The process of cleaning a semiconductor machine according to claim 3, wherein the contaminant level of the semiconductor machine is expressed by a cumulative workload of the semiconductor machine.

5. The process of cleaning a semiconductor machine according to claim 4, wherein the cumulative workload of the semiconductor machine is a cumulative value of working hours of the semiconductor machine or a cumulative number of processed wafers.

6. The process of cleaning a semiconductor machine according to claim 1, wherein the cleaning task is performed by a waferless auto clean technology.

7. The process of cleaning a semiconductor machine according to claim 1, wherein the fluoride compound is carbon tetrafluoride or hexafluoroethane.

8. A semiconductor machine, comprising:
a chamber for accommodating a semiconductor wafer and performing a semiconductor manufacturing process on the semiconductor wafer, wherein a titanium-based material is etched in the semiconductor manufacturing process; and
a cleaning module for providing a cleaning agent to clean the chamber, wherein the cleaning agent includes a gas mixture of a fluoride compound and oxygen.

9. The semiconductor machine according to claim 8, wherein the semiconductor manufacturing process performed in the chamber is an etching process of a titanium hard mask.

10. The semiconductor machine according to claim 8, wherein when a contaminant level of the semiconductor machine exceeds a threshold value, an automatic cleaning task of the cleaning module is activated to provide a cleaning agent to clean the chamber.

11. The semiconductor machine according to claim 10, wherein the contaminant level of the semiconductor machine is expressed by a cumulative workload of the semiconductor machine.

12. The semiconductor machine according to claim 11, wherein the cumulative workload of the semiconductor machine is a cumulative value of working hours of the semiconductor machine or a cumulative number of processed wafers.

13. The semiconductor machine according to claim 8, wherein the fluoride compound is carbon tetrafluoride or hexafluoroethane.

14. The semiconductor machine according to claim 8, wherein the chamber further comprises top power and bottom power, wherein during the cleaning module provides the cleaning agent to clean the chamber, the top power is turned on, but the bottom power is turned off.
